(19) United States
(12) Patent Application Publication
(10) Pub. No.: US 2007/0122927 A1
(43) Pub. Date: May 31, 2007

(54) Electrochemical cell structure and method of fabrication

(75) Inventors: Shunpu Li, Cambridgeshire (GB); Masaya Ishida, Cambridgeshire (GB)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/598,775

(22) Filed: Nov. 14, 2006

(30) Foreign Application Priority Data
Nov. 25, 2005 (GB) 0524077.5

(51) Int. Cl. H01L 21/00

(52) U.S. Cl. 438/48

(57) ABSTRACT

One limitation to the realisation of mass produced electrochemical cells is a lack of high resolution patterning techniques providing accurate-alignment. Accordingly a method of fabricating a patterned structure in the manufacture of an electrochemical cell comprising a soft-contact printing and ink-jet printing is provided.

### FIELD OF THE INVENTION

The present invention relates, in general, to an electrochemical cell and its method of manufacture. In particular, the present invention relates to the fabrication of a pixel array structure for a Dye-Sensitized Solar Cell (DSSC) using surface energy patterns that are defined by soft-contact printing.

### BACKGROUND OF THE INVENTION

A Dye-Sensitized Solar Cell (DSSC) functions as an electrochemical cell. U.S. Pat. No. 4,927,721 entitled “Photo-Electrochemical Cell”, by M. Gratzel et al., discloses a typical DSSC. As illustrated in FIG. 1: a typical DSSC 10 comprises; a substrate 1; a first transparent electrode 2; a metal oxide layer 3; a functional dye layer 4; an electrolyte layer 5: a second electrode 6; and a second substrate 7.

The DSSC 10 generates charge by the direct absorption of visible light. Since most metal oxides absorb light predominantly in the ultra-violet region of the electromagnetic spectrum, the functional dye 4 is absorbed onto the surface of the metal oxide layer 3 to extend the light absorption range of the metal oxide layer 3 into the visible light region.

In order to increase the amount of light that the metal oxide layer 3 can absorb, at least some portion of the metal oxide layer 3 is made porous, increasing the surface area of the metal oxide layer 3. This increased surface area can support an increased quantity of functional dye 4 resulting in increased light absorption and improving the energy conversion efficiency of the DSSC by more than 10%.

DSSC devices known in the art can be improved by fabricating the metal oxide layer as an array of micro-scale, high-density pixels. In order to fabricate and space the pixels as an array, device fabrication techniques such as micro-embossing, nano-imprinting and soft-contact printing can be employed because these techniques have become a key technology for mass production patterning techniques. Whilst these techniques allow for high-resolution patterning upon a substrate, tool alignment with previously defined structures upon the substrate is difficult. Accurate alignment is especially difficult in the case of large area, flexible substrates, due to the occurrence of warping, thermal expansion or shrinking of the substrate. Furthermore, in the case of roll-to-roll fabrication techniques, non-uniform distortions due to the necessary tensions applied to the substrate during transfer can cause further alignment difficulties.

One limitation to the realisation of mass produced DSSCs is therefore a lack of high resolution patterning techniques providing good alignment.

### SUMMARY OF THE INVENTION

According to a first embodiment of the present invention a method of fabricating a patterned structure in the manufacture of a Dye Sensitised Solar Cell is provided. The method comprising: depositing a first conductive layer upon a substrate; soft-contact printing to create a patterned template layer upon the first conductive layer and thereby forming a patterned array of adjacent cells spaced from one another upon the first conductive layer; and inkjet printing a metal oxide particle dispersion liquid on a plurality of cells in the patterned array of adjacent cells to form a patterned metal oxide layer.

According to a second embodiment of the present invention a method of fabricating a patterned structure in the manufacture of a Dye Sensitised Solar Cell is provided. The method comprising: depositing a first conductive layer upon a substrate; depositing a metal oxide layer upon the first conductive layer; soft-contact printing to create a patterned template layer upon the metal oxide layer and thereby forming a patterned array of adjacent cells spaced from one another upon the metal oxide layer; and inkjet printing a functional dye on a plurality of cells in the patterned array of adjacent cells.

In one embodiment the adjacent cells are spaced from one and another by a maximum separation of substantially 0.2 μm to 20 μm. In another embodiment the patterned array of adjacent cells is in the shape of a grid. In another embodiment the adjacent cells are shaped substantially square, rectangular, circular or hexagonal. In another embodiment the metal oxide particle dispersion liquid comprises a Titanium dioxide colloidal suspension. In a further embodiment a Dye Sensitised Solar Cell manufactured according to the above mentioned methods is provided.

The present invention therefore provides a cheap and high mass production patterning technique obviating or at least mitigating the problems associated with the prior art. The pre-patterned substrate effectively defines a resolution, while the device components are built up by subsequent inkjet printing.

### BRIEF DESCRIPTION OF THE DRAWINGS

Embodiments of the present invention will now be described by way of further example only and with reference to the accompanying drawings, in which:

FIG. 1 is a schematic diagram of a Dye-Sensitized Solar Cell (DSSC) as is known in the art;

FIG. 2 is a schematic diagram of a portion of a Dye-Sensitized Solar Cell (DSSC) useful for an understanding of the present invention; and

FIG. 3 is a schematic diagram of a method of fabricating a pixel array structure according to a first embodiment of the present invention.

### DETAILED DESCRIPTION

Throughout the following description, like reference numerals identify like parts.

FIG. 2 illustrates a portion of a Dye-Sensitized Solar Cell (DSSC) having an array of pixel cells 28. The DSSC comprises a substrate wafer 20 having a conductive first electrode layer 22 deposited thereon. The pixel array structure 28 is created by way of a bank structure 24 formed on the first electrode layer 22 prior to the application of a metal oxide layer 26. A patterned metal oxide layer 26 is subsequently formed by inkjet printing the metal oxide 26 into each pixel cell 28 to form an array of micro-scale, high density pixel cells 28 surrounded by the banks 24 such that no metal oxide bridges the bank structure 24. Finally, a functional dye layer is formed on the metal oxide layer 26.

Preferred embodiments of the present invention for the formation of pixel array structures or the like will now be described.

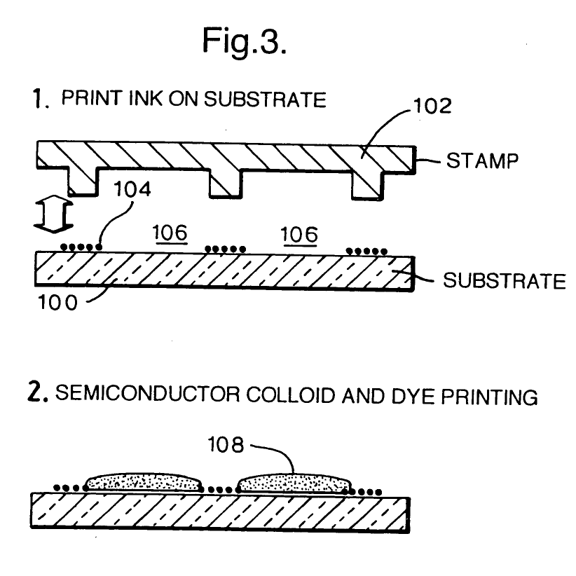

A method of fabricating a pixel array structure according to a first embodiment of the present invention includes a method of soft-contact printing and is illustrated in FIG. 3. A substrate 100 such as an Indium Tin Oxide (ITO) coated glass or an ITO coated polyethylene naphthalate (PEN) is subjected to an O₂ plasma treatment, so that the substrate surface becomes highly hydrophilic. A pre-structured polydimethylsiloxane (PDMS) stamp 102 inked with a hydrophobic material such as 1H, 1H, 2H, 2H-perfluorodecyl-triclorosilane solution (around 0.01 mol in hexane) is brought into firm contact with the substrate 100. A strong bonding with the surface molecules of the substrate 100 forms a self-assembled monolayer (SAM) pattern of the hydrophobic material. In this way a surface energy pattern 104 of hydrophobic material is formed upon the surface of the substrate 100. The surface energy pattern forms an array of pixel cells 106, each bounded by the hydrophobic SAM.

A titanium dioxide (TiO₂) colloidal suspension is inkjet printed upon the surface of the substrate 100 and targeted within the array of pixel cells 106. The solution 108 remains within the array of pixel cells 106 at the hydrophilic areas bordered by the hydrophobic pattern 104. This kind of hydrophobic SAM can be damaged by a high temperature process of more than 180° C. Therefore, thermal treatment of TiO₂ is preferable at less than 180° C. in order to take into account the functional dye inkjet process inside the hydrophobic SAM bank. In this embodiment, 120° C. annealing is used. However, other alternatives such as polymeric linking agent processes using for example poly(n-butyl titanate) and compression processes at pressures exceeding 200 kg/cm₂ can also be used. In addition, the functional dye layer is fabricated by using an inkjet process. After formation of the functional dye layer, the DSSC (not shown in FIG. 3) is completed by providing a counter electrode with a 20 μm distance to the TiO₂ layer and a redox electrolyte such as an iodine and potassium iodine mixture in acetonitrile, as is known in the art.

Soft-contact printing can also be used to make a surface energy pattern on a continuous metal oxide layer. By using the same type of stamp and SAM material as the first embodiment, a lyophilic/lyophobic pattern can be fabricated on the continuous metal oxide layer. Therefore, functional dye patterns can be deposited separately on the continuous metal oxide layer. The lyophobic pattern prevents the contamination by droplets from adjacent cells and this embodiment realises a high density of pixel cells.

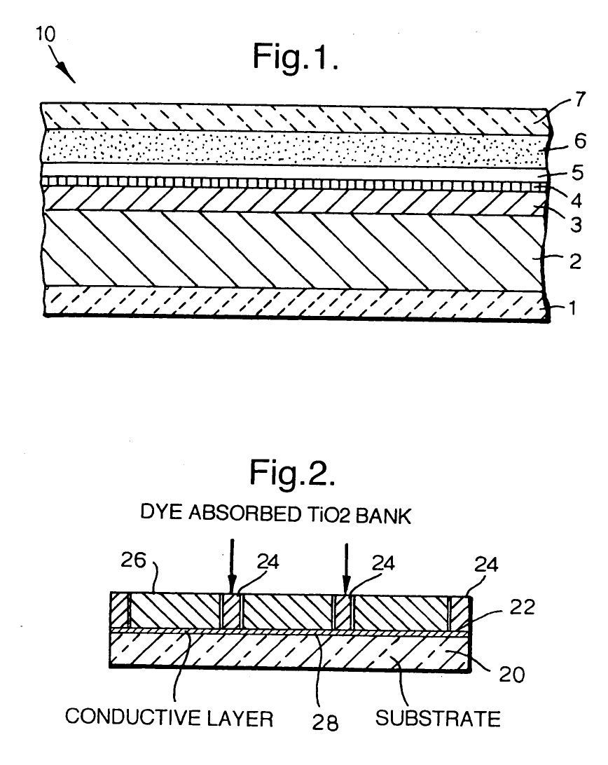

The foregoing description has been given by way of example only and a person skilled in the art will appreciate that modifications can be made without departing from the scope of the present invention. Other embodiments considered to be within the scope of the present invention include:
(1) Alternative ways of substrate surface treatment include O₂ plasma treatments, corona discharge treatments, UV-ozone treatments, chemical reaction, coating and vacuum deposition.
(2) Alternative materials for SAM application include materials with a tail group, such as fluro-, CH₃(CH₂)ₙ—, NH₂-—, —OH, —COOH etc. and a head group such as a silane, thiol etc depending oil the substrate used.
(3) The stump 102 can be made by PDMS or some other polymer such as a mixture of VDT-731 (vinymethylsiloxane-dimethylsiloxane trimethylsiloxy terminate) and HMS-301 (methyllhydrosiloxane-dimethylsiloxane copolymer).
(4) The first electrode, on which the structure is created, is not necessarily optically transparent for top viewing and it can be made of metals (Au, Cu, Ag etc.), conductive oxides (Indium Tin Oxide (ITO), SnO₂), conductive polymers etc.
(5) The fabrication process described above in connection with the first and second embodiments of the present invention can be used for both “sheet-to-sheet” and “roll-to-roll” processes and the substrate can be both flexible or rigid, such as glass, poly(ethylene naphthalate), poly(ethylene terepthalate), polycarbonates, polyethersulphone, and polyetheretherketon.
(6) The Titanium dioxide (TiO₂) colloidal suspension and ruthenium dye aqueous solution 108 need not be aqueous based but could comprise an alcohol based solvent. Other semiconductor colloids such as SnO₂, ZnO, Nb₂O₅, WO₃, SrTiO₃ can also be used.
(7) The present invention is applicable to the manufacture of electrochemical cells such as Dye Sensitised Solar Cells (DSSCs) and Electrocliromic Display Devices (ECDs). A typical ECD has a structure similar to that of a DSSC device as illustrated in FIG. 1. However, the functional dye layer 4 is replaced by all electrochromic material layer 4. An ECD undergoes a reversible colour change when an electric current or voltage is applied across the device. The nanostructure type ECD comprises a molecular monolayer of electrochromic material, which is transparent in the oxidised state and coloured in the reduced state.

1-11. (canceled)

12. A method of fabricating a patterned structure in the manufacture of a Dye Sensitised Solar Cell, the method comprising:
depositing a first conductive layer upon a substrate;
soft-contact printing to create a patterned template layer upon the first conductive layer and thereby forming a patterned array of adjacent cells spaced from one another upon the first conductive layer; and
inkjet printing a metal oxide particle dispersion liquid on a plurality of cells in the patterned array of adjacent cells to form a patterned metal oxide layer.

13. A method of fabricating a patterned structure in the manufacture of a Dye Sensitised Solar Cell, the method comprising:
depositing a first conductive layer upon a substrate;
depositing a metal oxide layer upon the first conductive layer;
soft-contact printing to create a patterned template layer upon the metal oxide layer and thereby forming a patterned array of adjacent cells spaced from one another upon the metal oxide layer; and
inkjet printing a functional dye on a plurality of cells in the patterned array of adjacent cells.

14. The method as claimed in claim 12, wherein the adjacent cells are spaced from one and another by a maximum separation of substantially 0.2 μm to 20 μm.

15. The method as claimed in claim 12, wherein the patterned array of adjacent cells is in the shape of a grid.

16. The method as claimed in claim 12, wherein the adjacent cells are shaped subtantially square, rectangular, circular or hexagonal.

17. The method as claimed in claim 12, wherein the metal oxide particle dispersion liquid comprises a Titanium dioxide colloidal suspension.

18. A Dye Sensitised Solar Cell manufactured according to claim 12.
